(19) United States
(12) Patent Application Publication
(10) Pub. No.: US 2007/0002601 A1
(43) Pub. Date: Jan. 4, 2007

(54) Semiconductor memory device

(75) Inventors: Eiji Hasunuma, Tokyo (JP); Keizo Kawakita, Tokyo (JP); Yoshinori Tanaka, Tokyo (JP); Noriaki Mikasa, Tokyo (JP)

Correspondence Address: MCDERMOTT WILL & EMERY LLP, 600 13TH STREET, N.W., WASHINGTON, DC, 20005-3096, US

(73) Assignee: Elpida Memory, Inc.

(21) Appl. No.: 11/472,336

(22) Filed: Jun. 22, 2006

(30) Foreign Application Priority Data
Jun. 22, 2005 (JP) 2005-182693

(51) Int. Cl. G11C 5/02

(52) U.S. Cl. 365/51

(57) ABSTRACT

Improved open bit line architecture is disclosed, comprising two types of memory cell groups, which are different in size from each other. Normal memory mats are arranged in a predetermined direction and each comprises smaller sized memory cells such as 6F² cells. Two end memory mats are arranged to sandwich the normal memory mats in the predetermined direction and comprises larger sized memory cells such as 8F² cells. With the architecture, some advantages of folded bit line structure are introduced into open bit line structure.

### BACKGROUND OF THE INVENTION

This invention relates to a semiconductor memory device and, especially, to an improved open bit line architecture applicable to the semiconductor memory device.

Architecture of semiconductor memory device such as dynamic random access memory (DRAM) device is generally divided into two types, open bit line architecture and folded bit line architecture. According to open bit line architecture, a pair of bit lines connected to a sense amplifier extend over different memory mats (memory cell arrays or memory sub-arrays). In other words, the pair of bit lines extend from the connected sense amplifier in opposite directions. On the other hand, according to folded bit line architecture, a pair of bit lines connected to a sense amplifier extend over a common memory mat. In other words, the pair of bit lines extend from the connected sense amplifier in the same direction.

Open bit line architecture can accommodate disposition of a memory cell at each cross point of bit lines and word lines. In addition, the architecture allows each memory cell to have a size of 6F². In practice, “F” or feature size is one-half of the bit line pitch. A memory cell having a size of 6F² is called “6F² cell”.

Folded bit line architecture does not allow disposition of a memory cell at each cross point of bit lines and word lines. In practice, a minimum realizable size for the architecture is 8F²; a memory cell having a size of 8F² is called “8F² cell”. 8F² cell is further divided into two types, i.e. 8F² half-pitch cell and 8F² quarter-pitch cell. In case of 8F² half-pitch cell, bit line contacts are arranged in a word line direction for each two bit lines. Namely, the distance between the two bit line contacts in the word line direction is 4F. In case of 8F² quarter-pitch cell, bit line contacts are arranged in a word line direction for each four bit lines. Namely, the distance between the two bit line contacts in the word line direction is 8F.

As apparent from the above, open bit line architecture has an advantage in very close packing of memory mats by the use of 6F² cells, in comparison with folded bit line architecture.

However, the conventional open bit line architecture requires dummy cells for two memory mats which are positioned at opposite ends in a row of memory mats; hereinafter each of two end mats of the memory mat raw is referred to as an “end memory mat”, while each of the others is referred to as a “normal memory mat.”According to the conventional open bit line architecture, the dummy cells occupy a half area of an end memory mat, as described in, for example, JP-A 2001-135075, the disclosure of which is incorporated herein by reference. In other words, the conventional architecture cannot make effective use of areas of the end memory mats.

Therefore, there is a need for improved open bit line architecture applicable to a semiconductor memory device, which can make effective use of areas of the end memory mats.

### SUMMARY OF THE INVENTION

According to one aspect of the present invention, a semiconductor memory device comprises: a plurality of normal memory mats arranged along a predetermined direction, each of the normal memory mats comprising a first predetermined number of first type memory cells, each of the first type memory cells having a first size; and two end memory mats arranged so that the normal memory mats are placed between the end memory mats in the predetermined direction, each of the end memory mats comprising a second predetermined number of second type memory cells, each of the second type memory cells having a second size larger than the first size.

An appreciation of the objectives of the present invention and a more complete understanding of its structure may be had by studying the following description of the preferred embodiment and by referring to the accompanying drawings.

### BRIEF DESCRIPTION OF THE DRAWINGS

FIG. 1 is a view schematically showing a DRAM device in accordance with a first embodiment of the present invention;

FIG. 2 is a view schematically showing an end memory mat and a normal memory mat, which are included in the DRAM device of FIG. 1; and

FIG. 3 is a view schematically showing an end memory mat and a normal memory mat, which are included in a DRAM device according to a second embodiment of the present invention.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DESCRIPTION OF PREFERRED EMBODIMENTS

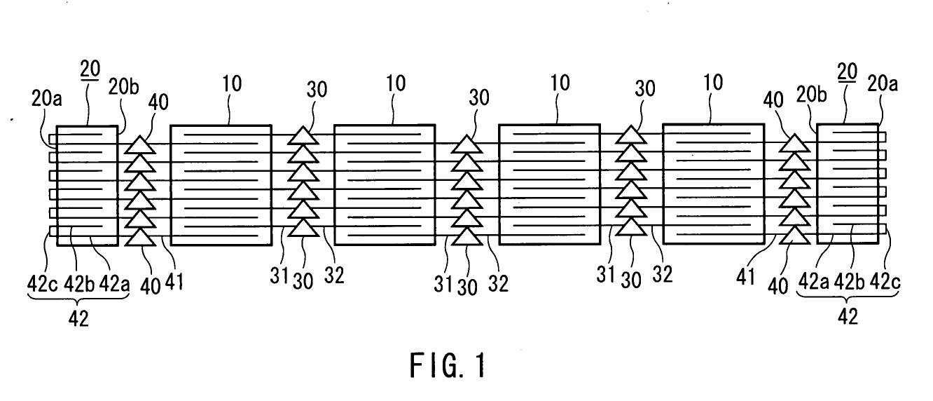

A semiconductor memory device according to a first embodiment of the present invention is a DRAM device with improved open bit line architecture. As shown in FIG. 1, the semiconductor memory device of the present embodiment comprises a plurality of normal memory mats 10 and two end memory mats 20. The normal memory mats 10 and the end memory mats 20 constitute a single memory mat row. In other words, the normal memory mats 10 and the end memory mats 20 are arranged along a common direction.

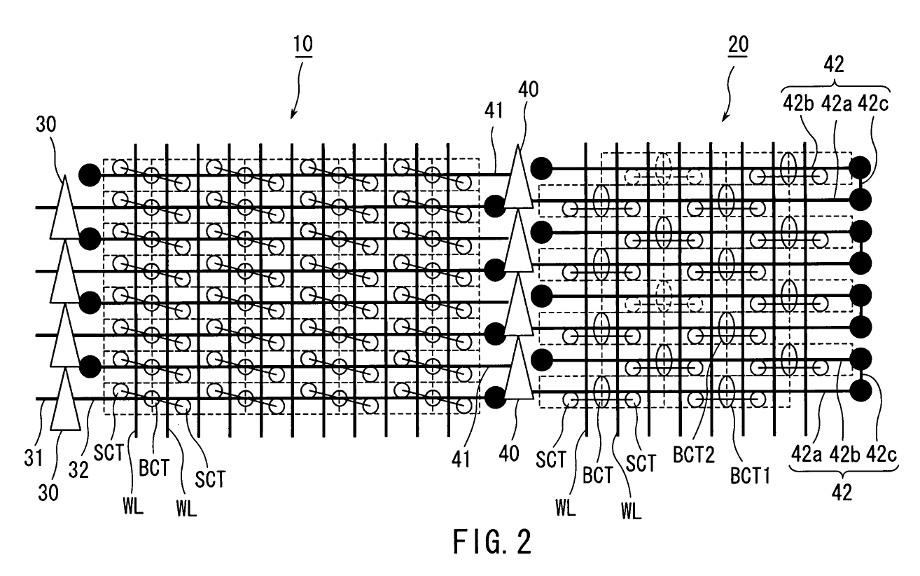

As shown in FIG. 2, the normal memory mat 10 comprises a first predetermined number of 6F² cells, while the end memory mat 20 comprises a second predetermined number of 8F² cells. In this embodiment, the 8F² cells are 8F² half-pitch cells. In FIG. 2, “WL”, “BCT” and “SCT” represent “word line”, “bit line contact” and “storage node contact”, respectively. The storage node contact is also referred to as “cylinder contact” if a capacitor of cell has a cylindrical shape.

Unlike the conventional architecture, the end memory mat 20 of the improved open bit line architecture of this embodiment does not comprise dummy cells. In other words, there is no area for dummy cell in the end memory mat 20 of the present embodiment. Therefore, the first predetermined number is larger than the second predetermined number. Specifically, the first predetermined number is about twice the second predetermined number in this embodiment.

Turning back to FIG. 1, sense amplifiers 30 are arranged between neighboring ones of the normal memory mats 10. To the sense amplifier 30, a pair of bit lines 31, 32 are connected. The bit lines 31, 32 extend over the normal memory mats 10 different from each other.

Likewise, sense amplifiers 40 are arranged between the end memory mat 20 and the normal memory mat 10 nearest to the end memory mat 20. For the sake of clarity, the sense amplifier 40 is referred to as “end sense amplifier” while the foregoing sense amplifier 30 is referred to as “normal sense amplifier”, although there is no functional difference therebetween.

To the sense amplifier 40, a pair of bit lines 41, 42 are connected. The bit lines 42, 41 extend over the end memory mat 20 and the normal memory mat 10 nearest thereto, respectively. Hereinafter, the bit line 41 extending over the normal memory mat 10 is referred to as “first bit line”, while the bit line 42 extending over the end memory mat 20 is referred to as “second bit line”.

As illustrated in FIG. 1, the first bit line 41 has a straight line shape like the bit line 31 or 32. On the other hand, the second bit line 42 has a J- or U-like shape or a hook shape.

More in detail, as shown in FIGS. 1 and 2, the end memory mat 20 has first and second edges 20b, 20a; the first edge 20b is near to the end sense amplifier 40, and the second edge 20a is far from the end sense amplifier 40. The second bit line 42 comprises first and second line segments 42a, 42b and a connection segment 42c. The first line segment 42a extends from the end sense amplifier 40 towards the second edge 20a. The connection segment 42c connects the first and the second line segments 42a, 42b in the vicinity of the second edge 20a. The second line segment 42b extends from the connection segment 42c toward the first edge 20b.

As apparent from the positional relationship between the bit line contacts BCT1 and BCT2, each two bit line contacts sandwich any one of the first line segment 42a or the second line segment 42b. The first and the second line segments 42a, 42b are arranged with a center-to-center distance equal to 2F.

With the above-described novel architecture, some advantages of folded bit line structure are introduced into open bit line structure. As the result, the conventional dummy cells can be omitted, and the size of the end memory mat can be reduced. For example, if each bit line is connected to 6F² cells of 2n bits (n is integer), the bit line requires, as a plane size, 24 nF² (=2n×6F²×2) in the conventional end memory mat. According to the present embodiment, if each bit line is connected to 8F² cells of 2n bits (n is integer), the bit line requires, as a plane size, 16 nF² (=2n×8F²) in the end memory mat because there are not required areas for dummy cells.

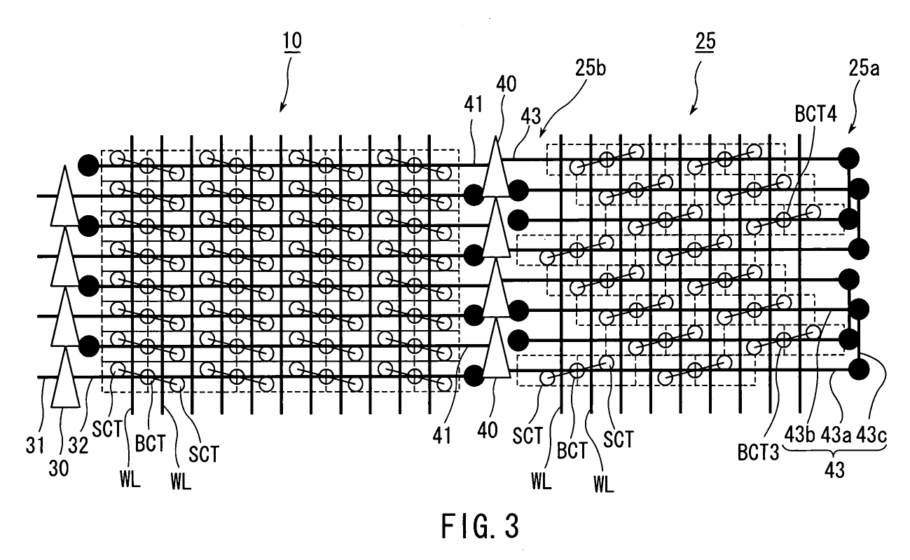

A semiconductor memory device according to a second embodiment of the present invention is a DRAM device with improved open bit line architecture, like the first embodiment. As shown in FIG. 3, each end memory mat 25 of the second embodiment comprises not 8F² half-pitch cells but 8F² quarter-pitch cells, unlike the first embodiment; like numerals in FIG. 3 denote like parts as in FIG. 2.

In detail, first and second bit lines 41 and 42 extend from the end sense amplifier 40 over the normal memory mat 10 and the end memory mat 25, respectively, as shown in FIG. 3. The end memory mat 25 has first and second edges 25b, 25a; the first edge 25b is near to the end sense amplifier 40, and the second edge 25a is far from the end sense amplifier 40. The second bit line 43 comprises first and second line segments 43a, 43b and a connection segment 43c. The first line segment 43a extends from the end sense amplifier 40 towards the second edge 25a. The connection segment 43c connects the first and the second line segments 43a, 43b in the vicinity of the second edge 25a. The second line segment 43b extends from the connection segment 43c toward the first edge 25b.

As apparent from the positional relationship between the bit line contacts BCT3 and BCT3, each two bit line contacts sandwich a combination of three line segments; one first line segment 43a and two second line segment 43b or two first line segment 43a and one second line segment 43b. The first and the second line segments 43a, 43b are arranged with a center-to-center distance equal to 4F. The corresponding pair of the first and the second line segments 43a and 43b sandwich any one of the first and the second line segments 43a and 43b which constitute another pair.

In this embodiment, the conventional dummy cells can be omitted, and the size of the end memory mat can be reduced. For example, according to the present embodiment, if each bit line is connected to 8F² cells of 2n bits (n is integer), the bit line requires, as a plane size, 16 nF² (=2n×8F²) in the end memory mat because there is not required dummy cells.

Although it is described that one pair of bit lines are connected to one sense amplifier, a plurality of pairs of bit lines may be connected to one sense amplifier.

While there has been described what is believed to be the preferred embodiment of the invention, those skilled in the art will recognize that other and further modifications may be made thereto without departing from the sprit of the invention, and it is intended to claim all such embodiments that fall within the true scope of the invention.

What is claimed is:

1. A semiconductor memory device comprising:
a plurality of normal memory mats arranged along a predetermined direction, each of the normal memory mats comprising a first predetermined number of first type memory cells, each of the first type memory cells having a first size; and
two end memory mats arranged so that the normal memory mats are placed between the end memory mats in the predetermined direction, each of the end memory mats comprising a second predetermined number of second type memory cells, each of the second type memory cells having a second size larger than the first size.

2. The semiconductor memory device according to claim 1, wherein the first predetermined number is larger than the second predetermined number.

3. The semiconductor memory device according to claim 1 comprising an open bit line architecture.

4. The semiconductor memory device according to claim 3, further comprising a plurality of sense amplifiers, a plurality of first bit lines and a plurality of second bit lines, wherein:
each of the sense amplifiers is positioned between one of the end memory mats and one of the normal memory mats nearest to the end memory mat and is connected to one of the first bit lines extending over the nearest normal memory mat and to one of the second bit lines extending over the end memory mats;
each of the end memory mats has a first edge near to the sense amplifiers and a second edge far from the sense amplifiers; and
each of the second bit lines comprises first and second line segments and a connection segment, the first line segment extending from the sense amplifier towards the second edge, the connection segment connecting the first and the second line segments in the vicinity of the second edge, the second line segment extending from the connection segment toward the first edge.

5. The semiconductor memory device according to claim 4, wherein each of the first type memory cells is a 6F² cell, while each of the second type memory cells is an 8F² cell.

6. The semiconductor memory device according to claim 5, wherein each of the second type memory cells is an 8F₂ half-pitch cell.

7. The semiconductor memory device according to claim 6, wherein the first and the second line segments are arranged to have a center-to-center distance equal to 2F.

8. The semiconductor memory device according to claim 5, wherein each of the second type memory cells is an 8F₂ quarter-pitch cell.

9. The semiconductor memory device according to claim 8, wherein the first and the second line segments are arranged to have a center-to-center distance equal to 4F.

10. A semiconductor memory device comprising:
a plurality of normal memory cell arrays arranged along a predetermined direction, each of the normal memory cell arrays comprising a first predetermined number of first type memory cells, each of the first type memory cells having a first size; and
two end memory cell arrays arranged so that the normal memory mats are placed between the end memory cell arrays in the predetermined direction, each of the end memory cell arrays comprising a second predetermined number of second type memory cells, each of the second type memory cells having a second size larger than the first size.

11. A semiconductor memory device comprising:
a plurality of normal memory sub-arrays arranged along a predetermined direction, each of the normal memory sub-arrays comprising a first predetermined number of first type memory cells, each of the first type memory cells having a first size; and
two end memory sub-arrays arranged so that the normal memory mats are placed between the end memory sub-arrays in the predetermined direction, each of the end memory sub-arrays comprising a second predetermined number of second type memory cells, each of the second type memory cells having a second size larger than the first size.
